(19) United States
(12) Patent Application Publication
(10) Pub. No.: US 2025/0022930 A1
(43) Pub. Date: Jan. 16, 2025

(54) SEMICONDUCTOR DEVICE

(71) Applicant: Samsung Electronics Co., Ltd., Suwon-si (KR)

(72) Inventors: Sunjung Lee, Suwon-si (KR); Donggon Yoo, Suwon-si (KR); Jeongwon Hwang, Suwon-si (KR)

(21) Appl. No.: 18/754,608

(22) Filed: Jun. 26, 2024

(30) Foreign Application Priority Data
Jul. 10, 2023 (KR) 10-2023-0089140
Dec. 1, 2023 (KR) 10-2023-0172405

(51) Int. Cl. H01L 29/423; H01L 23/522; H01L 23/528; H01L 23/532; H01L 29/06; H01L 29/417; H01L 29/49; H01L 29/775; H01L 29/786

(52) U.S. Cl. CPC H01L 29/42392; H01L 23/5226; H01L 23/528; H01L 23/5283; H01L 23/53228; H01L 29/0673; H01L 29/41733; H01L 29/4908; H01L 29/775; H01L 29/78696

(57) ABSTRACT

A semiconductor device may include a substrate including an active pattern, a channel pattern on the active pattern, the channel pattern including semiconductor patterns vertically stacked to be spaced apart from each other, a gate electrode on the plurality of semiconductor patterns, a gate contact electrically connected to the gate electrode, a first metal layer on the gate contact, the first metal layer including a first conductive via and a first interconnection pattern on the first conductive via, a second metal layer on the first metal layer, the second metal layer including a second conductive via and a second interconnection pattern on the second conductive via, and a diffusion prevention pattern between the first interconnection pattern and the second conductive via. A level of a bottom surface of the diffusion prevention pattern may be lower than a level of the topmost surface of the first interconnection pattern.

### CROSS-REFERENCE TO RELATED APPLICATIONS

This U.S. non-provisional patent application claims priority under 35 U.S.C. § 119 to Korean Patent Application Nos. 10-2023-0089140 and 10-2023-0172405, filed on Jul. 10, 2023 and Dec. 1, 2023, respectively, in the Korean Intellectual Property Office, the entire contents of which are hereby incorporated by reference.

### BACKGROUND

The present disclosure relates generally to a semiconductor device, and in particular, to a semiconductor device including a field-effect transistor.

A semiconductor device often includes an integrated circuit composed of metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize the semiconductor devices with high performance.

### SUMMARY

An embodiment of the inventive concept provides a semiconductor device with improved reliability.

An embodiment of the inventive concept provides a semiconductor device with improved electrical characteristics.

According to an embodiment of the inventive concept, a semiconductor device may include a substrate including an active pattern, a channel pattern on the active pattern, the channel pattern including a plurality of semiconductor patterns, which are vertically stacked to be spaced apart from each other, a gate electrode on the plurality of semiconductor patterns, a gate contact electrically connected to the gate electrode, a first metal layer on the gate contact, the first metal layer including a first conductive via and a first interconnection pattern on the first conductive via, a second metal layer on the first metal layer, the second metal layer including a second conductive via and a second interconnection pattern on the second conductive via, and a diffusion prevention pattern between the first interconnection pattern and the second conductive via. A level of a bottom surface of the diffusion prevention pattern may be lower than a level of the topmost surface of the first interconnection pattern.

According to an embodiment of the inventive concept, a semiconductor device may include a substrate including an active pattern, a channel pattern on the active pattern, the channel pattern including a plurality of semiconductor patterns, which are vertically stacked to be spaced apart from each other, a source/drain pattern connected to the channel pattern, a gate electrode on the plurality of semiconductor patterns, an active contact electrically connected to the source/drain pattern, a metal interconnection structure on the active contact, the metal interconnection structure including a conductive via and an interconnection pattern on the conductive via, and a diffusion prevention pattern provided between the interconnection pattern and the conductive via. A level of a top surface of the diffusion prevention pattern may be different from a level of the bottommost surface of the interconnection pattern in contact with the diffusion prevention pattern, and the diffusion prevention pattern may include ruthenium oxide.

According to an embodiment of the inventive concept, a semiconductor device may include a substrate including an active pattern, a device isolation layer defining the active pattern, a channel pattern on the active pattern, the channel pattern including a plurality of semiconductor patterns, which are vertically stacked to be spaced apart from each other, a gate electrode on the plurality of semiconductor patterns, a gate insulating layer between the gate electrode and adjacent ones of the semiconductor patterns, a gate contact electrically connected to the gate electrode, a first metal layer on the substrate, the first metal layer including a first conductive via, a first interconnection pattern on the first conductive via, and a first via insulating layer enclosing (i.e., extending around) the first conductive via, a second metal layer disposed on the first metal layer, the second metal layer including a second conductive via and a second interconnection pattern on the second conductive via, a diffusion prevention pattern between the first conductive via and the first interconnection pattern, and a selection barrier pattern enclosing a portion of a bottom surface of the first interconnection pattern and a side surface of the first interconnection pattern. A side surface of the diffusion prevention pattern may be in contact with the first interconnection pattern, the selection barrier pattern, and the first via insulating layer.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIGS. 1 to 3 are conceptual plan view diagrams illustrating logic cells of a semiconductor device according to an embodiment of the inventive concept;

FIG. 4 is a plan view illustrating a semiconductor device according to an embodiment of the inventive concept;

FIGS. 5A to 5D are cross-sectional views taken along lines A-A′, B-B′, C-C′, and D-D′ of FIG. 4, respectively;

FIGS. 6A to 6D are enlarged cross-sectional views, each of which illustrates a portion ‘P’ of FIG. 5C, according to an embodiment of the inventive concept;

FIGS. 7A to 7C are cross-sectional views illustrating intermediate processes in an example method of fabricating the semiconductor device of FIG. 6A, according to one or more embodiments of the inventive concept;

FIGS. 8A to 8C are cross-sectional views illustrating intermediate processes in an example method of fabricating the semiconductor device of FIG. 6B, according to one or more embodiments of the inventive concept;

FIGS. 9A to 9D are cross-sectional views illustrating intermediate processes in an example method of fabricating the semiconductor device of FIG. 6C, according to one or more embodiments of the inventive concept; and

FIGS. 10A to 10C are cross-sectional views illustrating intermediate processes in an example method of fabricating the semiconductor device of FIG. 6D, according to one or more embodiments of the inventive concept.

### DETAILED DESCRIPTION

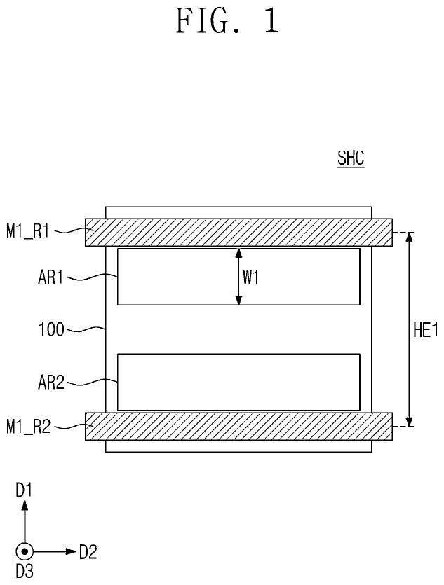

FIGS. 1 to 3 are conceptual plan view diagrams illustrating logic cells of a semiconductor device according to an embodiment of the inventive concept.

Referring to FIG. 1, a single height cell SHC may be provided. In detail, a first power line M1_R1 and a second power line M1_R2 may be provided on a substrate 100. The first power line M1_R1 may be a conduction path, to which a source voltage (VSS) (e.g., a ground voltage) is provided. The second power line M1_R2 may be a conduction path, to which a drain voltage (VDD) (e.g., a power voltage) is provided. Each of the first and second power lines M1_R1 and M1_R2, respectively, may extend in a second direction D2 parallel to an upper surface of the substrate 100 and may be separated from one another in a first direction parallel to the upper surface of the substrate 100 and perpendicular to the second direction D2.

The single height cell SHC may be defined between the first power line M1_R1 and the second power line M1_R2. The single height cell SHC may include one first active region AR1 and one second active region AR2. One of the first and second active regions AR1 and AR2 may be a p-channel metal-oxide-semiconductor field-effect transistor (PMOSFET) region, and the other of the first and second active regions AR1 and AR2 may be an n-channel metal-oxide-semiconductor field-effect transistor (NMOSFET) region. In other words, the single height cell SHC may have a complementary metal-oxide-semiconductor (CMOS) structure provided between the first and second power lines M1_R1 and M1_R2.

Each of the first and second active regions AR1 and AR2 may have a first width WI in the first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

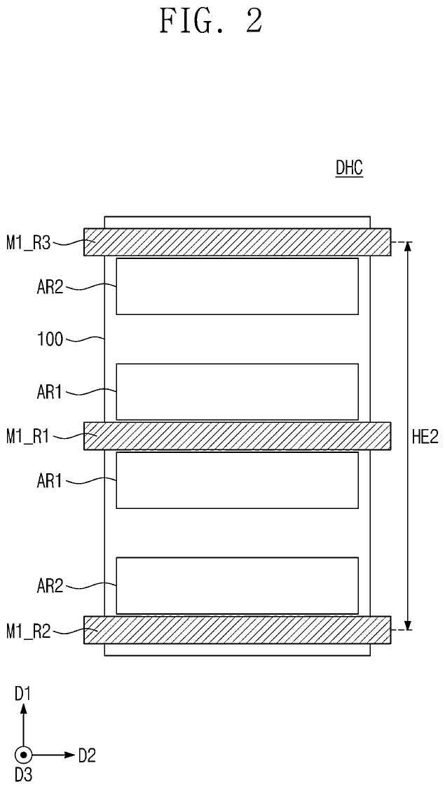

Referring to FIG. 2, a double height cell DHC may be provided. In detail, a first power line M1_R1, a second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the source voltage (VSS) is provided. Each of the first, second and third power lines M1_R1, M1_R2 and M1_R3, respectively, may extend in the second direction D2 and may be separated from one another in the first direction D1.

The double height cell DHC may be defined between the second power line M1_R2 and the third power line M1_R3. The double height cell DHC may include a pair of first active regions AR1 and a pair of second active regions AR2.

One of the second active regions AR2 may be adjacent to the second power line M1_R2. The other of the second active regions AR2 may be adjacent to the third power line M1_R3. The pair of the first active regions AR1 may be adjacent to the first power line M1_R1. When viewed in a plan view, the first power line M1_R1 may be disposed between the pair of the first active regions AR1.

A length of the double height cell DHC in the first direction D1 may be defined as a second height HE2. The second height HE2 may be about two times (i.e., twice) the first height HE1 of FIG. 1. The pair of the first active regions AR1 of the double height cell DHC may be combined to serve as a single active region.

In an embodiment, the double height cell DHC shown in FIG. 2 may be defined as a multi-height cell. Although not shown, the multi-height cell may include a triple height (or higher) cell whose cell height is about three times that of the single height cell SHC.

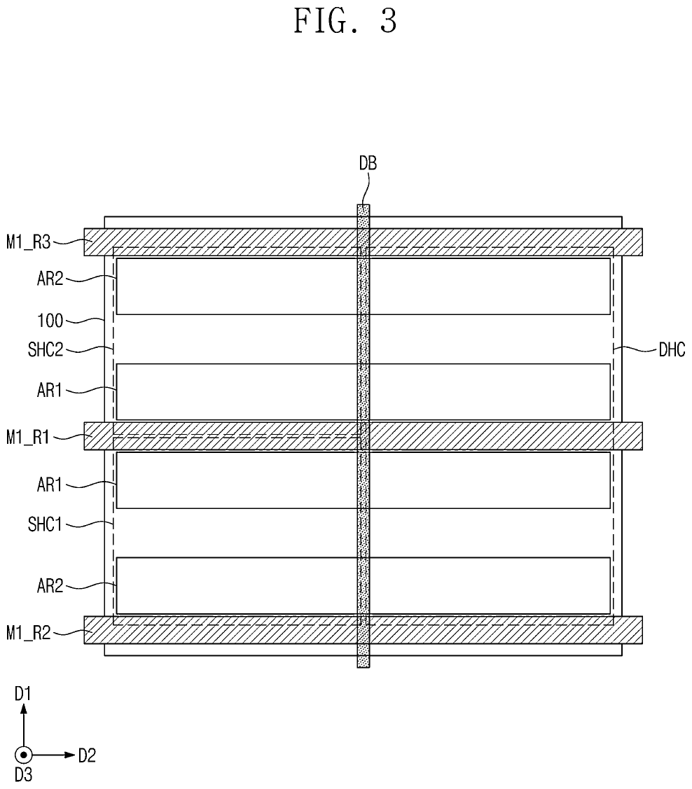

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in the second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

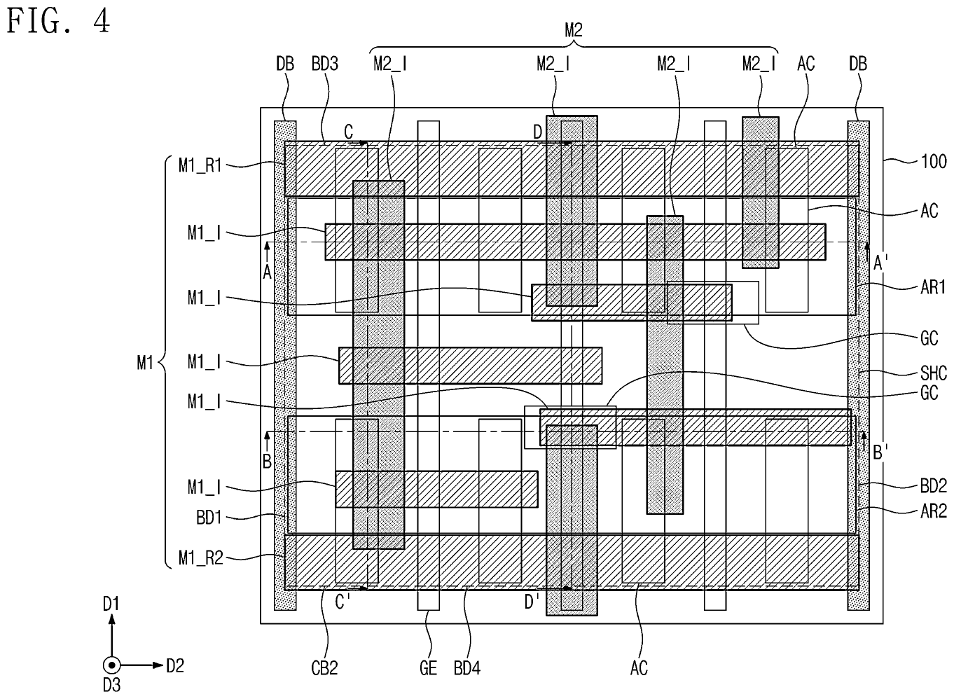

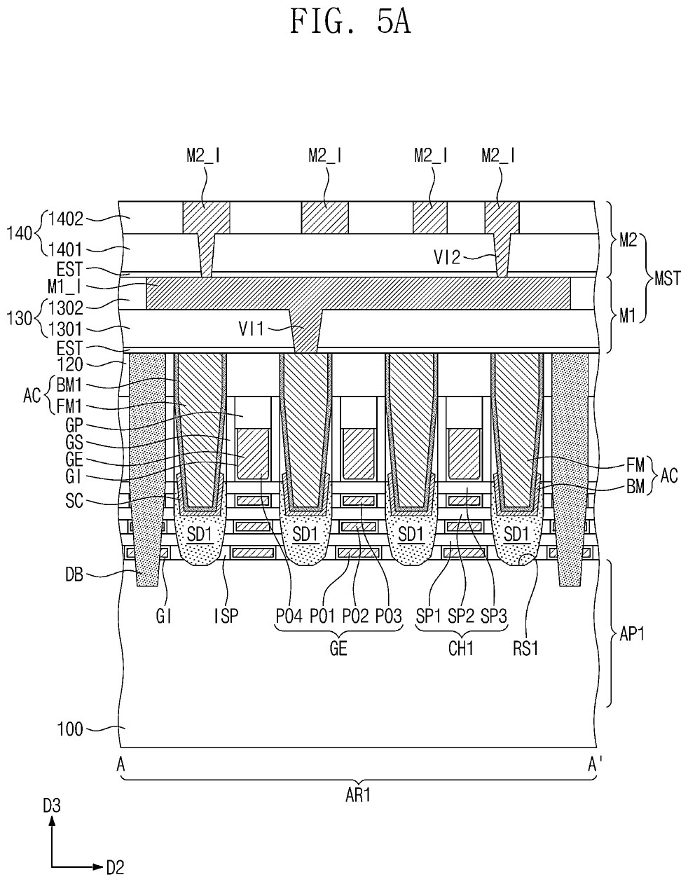

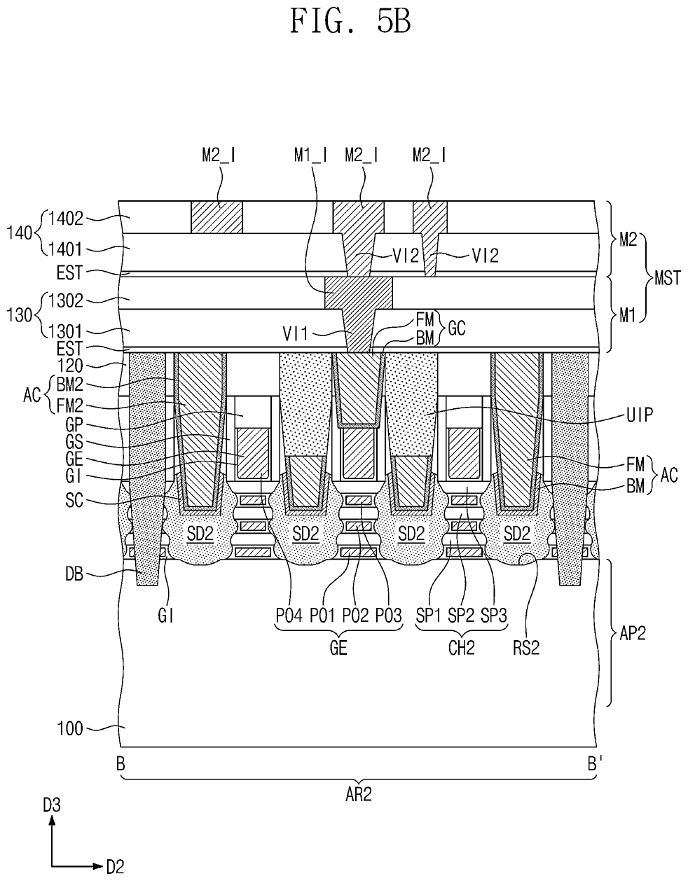

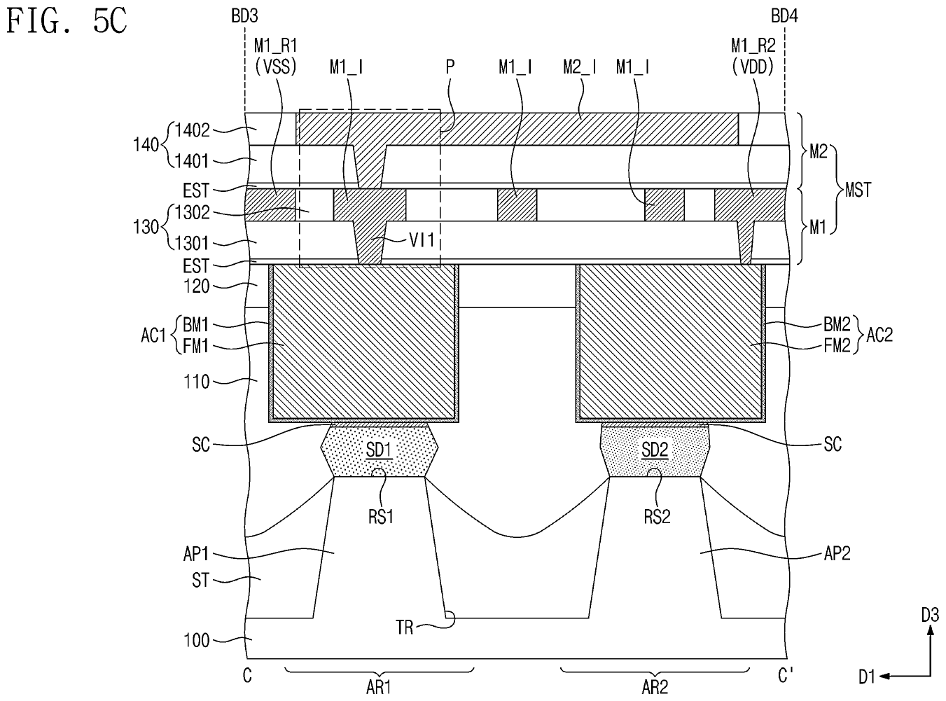

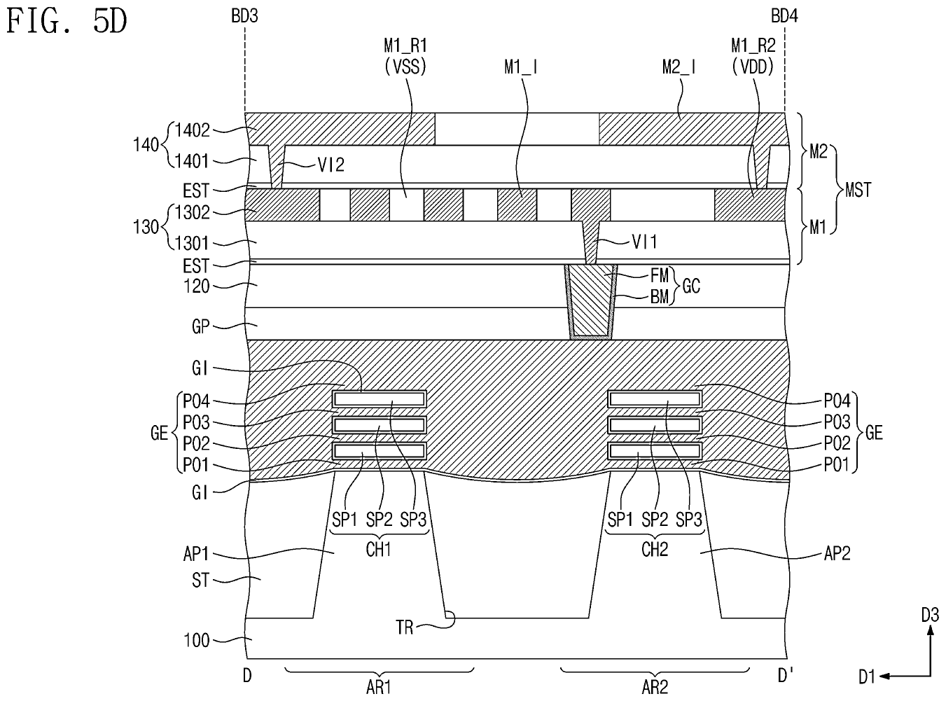

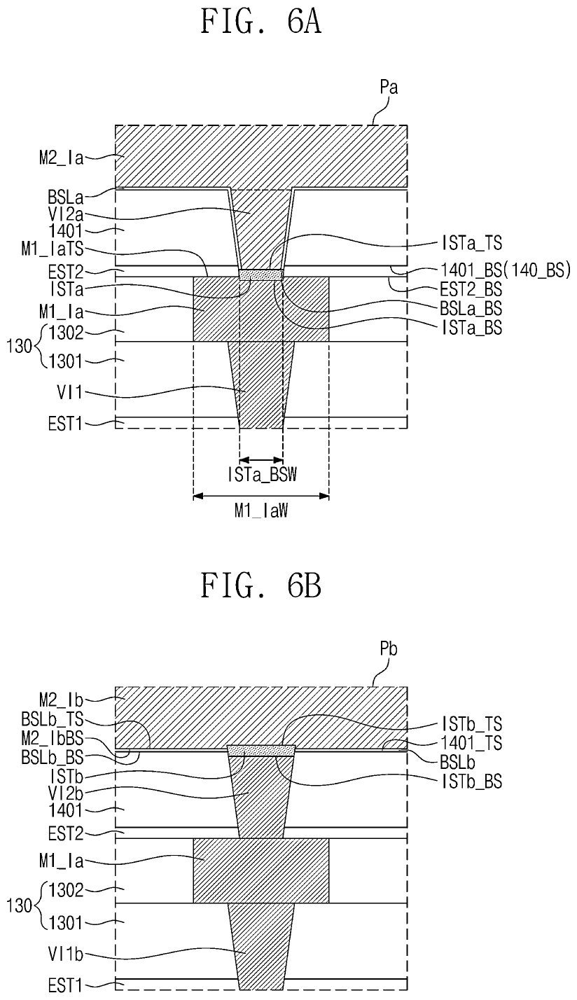

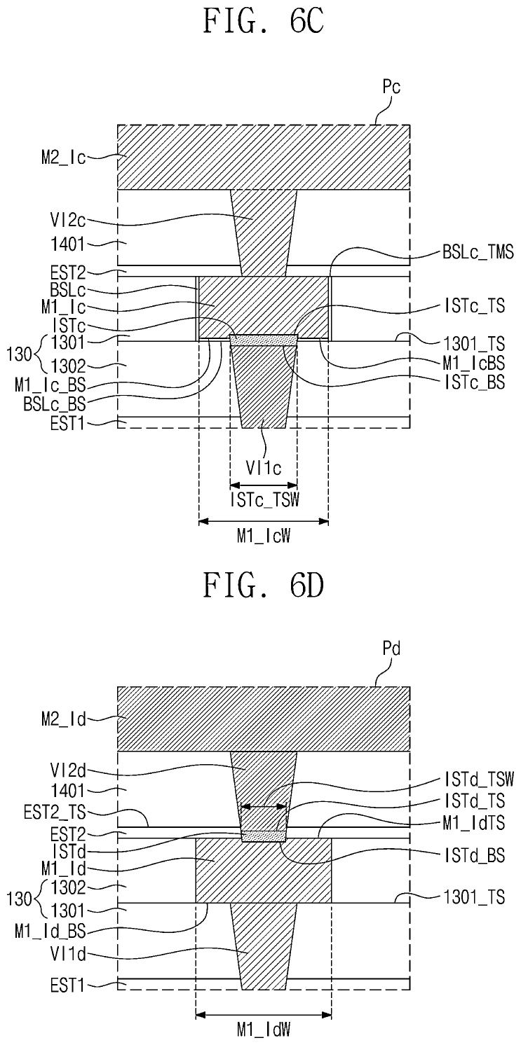

FIG. 4 is a plan view illustrating at least a portion of an example semiconductor device according to an embodiment of the inventive concept. FIGS. 5A to 5D are cross-sectional views taken along lines A-A′, B-B′, C-C′, and D-D′ of FIG. 4, respectively. FIGS. 6A to 6D are enlarged cross-sectional views, each of which illustrates a portion ‘P’ of FIG. 5C according to an embodiment of the inventive concept. The semiconductor device of FIGS. 4 and 5A to 5D may be one example of the single height cell SHC of FIG. 1, although embodiments are not limited thereto.

Referring to FIGS. 4 and 5A to 5D, the single height cell SHC may be provided on the substrate 100. Logic transistors constituting a logic circuit may be disposed on the single height cell SHC. The substrate 100 may be a semiconductor substrate that is formed of or includes silicon, germanium, silicon germanium, a compound semiconductor material, or the like, although embodiments are not limited thereto. In an embodiment, the substrate 100 may be a silicon wafer.

The substrate 100 may include the first active region AR1 and the second active region AR2. Each of the first and second active regions AR1 and AR2 may extend in the second direction D2. In an embodiment, the first active region AR1 may be an NMOSFET region, and the second active region AR2 may be a PMOSFET region.

A first active pattern AP1 and a second active pattern AP2 may be defined by a trench TR, which is formed in an upper portion of the substrate 100 and extends into the substrate 100 in the third direction D3. The first active pattern AP1 may be provided on the first active region AR1, and the second active pattern AP2 may be provided on the second active region AR2. The first and second active patterns AP1 and AP2 may extend in the second direction D2. Each of the first and second active patterns AP1 and AP2 may be a vertically-protruding portion of the substrate 100.

A device isolation layer ST may be provided on the substrate 100. The device isolation layer ST may be provided to fill the trench TR. The term “fill” (or “filling,” “filled,” or like terms) as may be used herein is intended to refer broadly to either completely filling a defined space (e.g., trench TR) or partially filling the defined space; that is, the defined space need not be entirely filled but may, for example, be partially filled or have voids or other spaces throughout. The device isolation layer ST may include a silicon oxide layer. The device isolation layer ST may not cover first and second channel patterns CH1 and CH2 to be described below. The term “cover” (or “covering,” or like terms) as may be used herein is intended to broadly refer to a material, layer or structure being on or over another material, layer or structure, but does not require the material, layer or structure to entirely cover the other material, layer or structure.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked in the third direction D3. The first to third semiconductor patterns SP1, SP2, and SP3 may be spaced apart from each other in a vertical direction (i.e., the third direction D3).

Each of the first to third semiconductor patterns SP1, SP2, and SP3 may be formed of or include silicon (Si), germanium (Ge) or silicon-germanium (SiGe). For example, each of the first to third semiconductor patterns SP1, SP2, and SP3 may be formed of or include crystalline silicon (e.g., single crystalline silicon). In an embodiment, the first to third semiconductor patterns SP1, SP2, and SP3 may be stacked nanosheets.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be interposed between a pair of the first source/drain patterns SD1. That is, each pair of the first source/drain patterns SD1 may be connected to each other by the first to third semiconductor patterns SP1, SP2, and SP3 stacked.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be interposed between a pair of the second source/drain patterns SD2. That is, each pair of the second source/drain patterns SD2 may be connected to each other by the first to third semiconductor patterns SP1, SP2, and SP3 stacked.

The first and second source/drain patterns SD1 and SD2 may be epitaxial patterns, which are formed by a selective epitaxial growth (SEG) process. In an embodiment, a top surface of each of the first and second source/drain patterns SD1 and SD2 may be higher than a top surface of the third (topmost) semiconductor pattern SP3. In another embodiment, a top surface of at least one of the first and second source/drain patterns SD1 and SD2 may be at substantially the same level as the top surface of the third semiconductor pattern SP3; that is, the top surface of at least one of the first and second source/drain patterns SD1 and SD2 may be substantially coplanar with the top surface of the third semiconductor pattern SP3 in the third direction D3, relative to the upper surface of the substrate 100 as a reference layer.

In an embodiment, the first source/drain patterns SD1 may be formed of or include the same semiconductor element (e.g., Si) as the substrate 100. The second source/drain patterns SD2 may include a semiconductor material (e.g., SiGe) whose lattice constant is greater than that of the substrate 100. In this case, the pair of the second source/drain patterns SD2 may exert a compressive stress on the second channel pattern CH2 therebetween.

In an embodiment, the second source/drain pattern SD2 may have an uneven or embossing side surface. That is, the side surface of the second source/drain pattern SD2 may have a wavy profile in the third direction D3. The side surface of the second source/drain pattern SD2 may protrude toward first to third inner electrodes PO1, PO2, and PO3 of a gate electrode GE to be described below.

The gate electrodes GE may be provided on the first and second channel patterns CH1 and CH2. Each of the gate electrodes GE may extend in the first direction D1 to cross the first and second channel patterns CH1 and CH2. Each of the gate electrodes GE may be vertically overlapped with the first and second channel patterns CH1 and CH2. The term “overlapped” (or “overlapping,” or like terms), as used herein, is intended to broadly refer to a first element that intersects with at least a portion of a second element in the vertical direction (i.e., the third direction D3), but does not require that the first and second elements be completely aligned with one another in a horizontal plane (i.e., in the first direction D1 and/or second direction D2). The gate electrodes GE may be arranged at a first pitch in the second direction D2. The gate electrodes GE may extend in the first direction D1 and may be arranged in the second direction D2 crossing the first direction D1.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., multi-bridge channel field-effect transistor (MBCFET) or gate-all-around field-effect transistor (GAAFET)) in which the gate electrode GE is provided to three-dimensionally surround the channel pattern. The term “surround” (or “surrounding,” or like terms) as used herein is intended to broadly refer to an element, structure or layer that extends around, envelops, encircles, or encloses another element, structure or layer on all sides, although breaks or gaps may also be present. Thus, for example, a material layer having voids therein may still “surround” another layer which it encircles.

On the first active region AR1, inner spacers ISP may be respectively interposed between the first to third inner electrodes PO1, PO2, and PO3 of the gate electrode GE and the first source/drain pattern SD1. Each of the first to third inner electrodes PO1, PO2, and PO3 of the gate electrode GE may be spaced apart from the first source/drain pattern SD1, with the inner spacer ISP interposed therebetween. The inner spacer ISP may prevent a leakage current from the gate electrode GE.

Referring back to FIGS. 4 and 5A to 5D, a pair of gate spacers GS may be respectively disposed on the opposite side surfaces of the outer electrode PO4 of the gate electrode GE. The gate spacers GS may extend along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, to be described below, in the third direction D3. In an embodiment, the gate spacers GS may be formed of or include at least one of SiCN, SiCON, or SiN. In another embodiment, the gate spacers GS may be a multi-layered structure, which is formed of or includes at least two different materials selected from SiCN, SiCON, and SiN. In an embodiment, the gate spacer GS may be formed of or include a Si-containing insulating material. The gate spacer GS may be used as an etch stop layer in a process of forming active contacts AC to be described below. The active contacts AC may be formed by a self-alignment process using the gate spacer GS.

A gate capping pattern GP may be provided on the gate electrode GE. The gate capping pattern GP may extend along the gate electrode GE and in the first direction D1. The gate capping pattern GP may be formed of or include a material having an etch selectivity with respect to first and second interlayer insulating layers 110 and 120, which will be described below. In detail, the gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to third semiconductor patterns SP1, SP2, and SP3. The gate insulating layer GI may cover a top surface of the device isolation layer ST below the gate electrode GE.

In an embodiment, the gate insulating layer GI may include a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In another embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected capacitors has a negative capacitance, a total capacitance of the serially-connected capacitors may have a positive value and may be greater than an absolute value of each capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. The dopants may include at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In the case where the dopants are aluminum (Al), a content of aluminum in the ferroelectric layer may range from about 3 to 8 at % (atomic percentage). Here, the content of the dopants (e.g., aluminum atoms) may be a ratio of the number of aluminum atoms to the number of hafnium and aluminum atoms.

In the case where the dopants are silicon (Si), a content of silicon in the ferroelectric layer may range from about 2 at % to 10 at %. In the case where the dopants are yttrium (Y), a content of yttrium in the ferroelectric layer may range from about 2 at % to 10 at %. In the case where the dopants are gadolinium (Gd), a content of gadolinium in the ferroelectric layer may range from about 1 at % to 7 at %. In the case where the dopants are zirconium (Zr), a content of zirconium in the ferroelectric layer may range from about 50 at % to 80 at %.

The paraelectric layer may have the paraelectric property. The paraelectric layer may be formed of or include at least one of, for example, silicon oxide and/or high-k metal oxides. The metal oxides, which can be used as the paraelectric layer, may include at least one of, for example, hafnium oxide, zirconium oxide, and/or aluminum oxide, but the inventive concept is not limited to these examples.

The ferroelectric layer and the paraelectric layer may be formed of or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property, only when its thickness is in a specific range. In an embodiment, the ferroelectric layer may have a thickness ranging from about 0.5 nanometers (nm) to 10 nm, but the inventive concept is not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring back to FIGS. 4 and 5A to 5D, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a cross-sectional thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). In an embodiment, the outer electrode PO4 of the gate electrode GE may include the first metal pattern and the second metal pattern on the first metal pattern.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with a top surface of the gate capping pattern GP and a top surface of the gate spacer GS in the third direction D3. A second interlayer insulating layer 120 may be disposed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110 to 140 may include a silicon oxide layer.

The single height cell SHC may have a first border BD1 and a second border BD2, which are opposite to each other in the second direction D2. The first and second borders BD1 and BD2 may extend in the first direction D1. The single height cell SHC may have a third border BD3 and a fourth border BD4, which are opposite to each other in the first direction D1. The third and fourth borders BD3 and BD4 may extend in the second direction D2.

A pair of division structures DB, which are opposite to each other in the second direction D2, may be provided at both sides of the single height cell SHC. For example, the pair of the division structures DB may be respectively provided on the first and second borders BD1 and BD2 of the single height cell SHC. The division structure DB may extend in the first direction D1 to be parallel to the gate electrodes GE. A pitch between the division structure DB and the gate electrode GE adjacent thereto may be equal to the first pitch.

The division structure DB may penetrate (i.e., extend into or through) the first and second interlayer insulating layers 110 and 120 and may extend into the active patterns AP1 or AP2. The division structure DB may penetrate an upper portion of each of the first and second active patterns AP1 and AP2. The division structure DB may electrically separate an active region of each of the single height cell SHC from an active region of a neighboring cell.

The active contacts AC may be provided to penetrate the first and second interlayer insulating layers 110 and 120 and to be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern that extends in the first direction D1.

The active contacts AC may be self-aligned contacts. For example, the active contact AC may be formed by a self-alignment process using the gate capping pattern GP and the gate spacer GS. For example, the active contacts AC may cover at least a portion of a side surface of the gate spacer GS. Although not shown, the active contact AC may be provided to cover a portion of the top surface of the gate capping pattern GP.

Metal-semiconductor compound layers SC (e.g., silicide layers) may be respectively interposed between a first active contact AC1 and the first source/drain pattern SD1 and between a second active contact AC2 and the second source/drain pattern SD2. The first and second active contact AC1 or AC2 may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide, although embodiments are not limited thereto. The first and second active contacts AC1 and AC2 will be described in more detail with reference to FIGS. 5A to 5C, 6A, and 6B.

Gate contacts GC may be provided to penetrate the second interlayer insulating layer 120 and the gate capping pattern GP and may be electrically connected to the gate electrodes GE, respectively. When viewed in a plan view, the gate contacts GC may be respectively overlapped with the first and second active regions AR1 and AR2. In an embodiment, the gate contact GC may be provided on the second active pattern AP2 (e.g., see FIG. 5B).

In an embodiment, referring to FIG. 5B, a region, which is placed on the second active contact AC2 adjacent to the gate contact GC, may be filled with an upper insulating pattern UIP. A bottom surface of the upper insulating pattern UIP may be lower than a bottom surface of the gate contact GC. That is, a top surface of the second active contact AC2 adjacent to the gate contact GC may be formed at a level, which is lower than the bottom surface of the gate contact GC, by the upper insulating pattern UIP. Accordingly, it may be possible to prevent the gate contact GC and the second active contact AC2, which are adjacent to each other, from being in contact with each other and thereby to prevent a short circuit issue from occurring therebetween.

The first active contact AC1 may include a first conductive pattern FM1 and a first barrier pattern BM1 enclosing (i.e., extending around) the first conductive pattern FM1, and the second active contact AC2 may include a second conductive pattern FM2 and a second barrier pattern BM2 enclosing (i.e., extending around) the second conductive pattern FM2. The gate contact GC may include a conductive pattern FM and a barrier pattern BM enclosing (i.e., extending around) the conductive pattern FM. For example, each of the conductive patterns FM1, FM2, and FM may be formed of or include at least one of metallic materials (e.g., aluminum, copper, tungsten, molybdenum, and cobalt). Each of the barrier patterns BM1, BM2, and BM may cover side and bottom surfaces of each of the conductive patterns FM1, FM2, and FM. Each of the barrier patterns BM1, BM2, and BM may include a metal layer or a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

A metal interconnection structure MST may be disposed in the third interlayer insulating layer 130 and the fourth interlayer insulating layer 140. The metal interconnection structure MST may include a first metal layer M1 and a second metal layer M2.

The first metal layer M1 may be provided. In an embodiment, the first metal layer M1 may include the first power line M1_R1, the second power line M1_R2, and first interconnection patterns M1_I. Each of the interconnection lines M1_R1, M1_R2, and M1_I of the first metal layer M1 may extend in the second direction D2 and be parallel to each other.

In detail, the first and second power lines M1_R1 and M1_R2 may be provided on the third and fourth borders BD3 and BD4 of the single height cell SHC, respectively. The first power line M1_R1 may extend along the third border BD3 and in the second direction D2. The second power line M1_R2 may extend along the fourth border BD4 and in the second direction D2.

The first interconnection patterns M1_I of the first metal layer M1 may be disposed between the first and second power lines M1_R1 and M1_R2. The first interconnection patterns M1_I of the first metal layer M1 may be arranged at a second pitch in the first direction D1. The second pitch may be smaller than the first pitch. A linewidth of each of the first interconnection patterns M1_I may be smaller than a linewidth of each of the first and second power lines M1_R1 and M1_R2.

The first metal layer M1 may further include first conductive vias VI1. The first conductive vias VI1 may be respectively disposed below the interconnection lines M1_R1, M1_R2, and M1_I of the first metal layer M1. The active contact AC and the interconnection line of the first metal layer M1 may be electrically connected to each other through the first conductive via VI1. The gate contact GC and the interconnection line of the first metal layer M1 may be electrically connected to each other through the first conductive via VI1.

The interconnection line of the first metal layer M1 and the first conductive via VI1 thereunder may be formed by separate processes. That is, each of the interconnection line and the first conductive via VI1 of the first metal layer M1 may be formed by a single damascene process. The semiconductor device according to the present embodiment may be fabricated using a sub-20 nm process.

The second metal layer M2 may be provided in the fourth interlayer insulating layer 140. The second metal layer M2 may include a plurality of second interconnection patterns M2_I. Each of the second interconnection patterns M2_I of the second metal layer M2 may be a line- or bar-shaped pattern that extends in the first direction D1. That is, the second interconnection patterns M2_I may extend in the first direction D1 and be parallel to each other.

The second metal layer M2 may further include second conductive vias VI2, which are respectively provided below the second interconnection patterns M2_I. The interconnection lines of the first and second metal layers M1 and M2 may be electrically connected to each other through the second conductive via VI2. The interconnection line of the second metal layer M2 and the second conductive via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, ruthenium, molybdenum, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

The first and second active contacts AC1 and AC2 will be described in more detail with reference to FIGS. 5A to 5D. The first active contact AC1 may include the first conductive pattern FM1 and a first barrier pattern BM1 enclosing (i.e., extending around) the first conductive pattern FM1. The first active contact AC1 may be vertically overlapped (in the third direction D3) with the first source/drain pattern SD1. The first active contact AC1 may be electrically connected to the first source/drain pattern SD1. For example, a lower portion of the first active contact AC1 may be inserted into (i.e., contact) the first source/drain pattern SD1, and the first active contact AC1 and the first source/drain pattern SD1 may be in contact with each other through the inserted lower portion.

The silicide layer SC may be interposed between the first active contact AC1 and the first source/drain pattern SD1. The silicide layer SC may be a metal-semiconductor compound layer. The silicide layer SC may lower a contact resistance between the first active contact AC1 and the first source/drain pattern SD1. That is, the first active contact AC1 may be electrically connected to the first source/drain pattern SD1 through the silicide layer SC.

The metal interconnection structure MST including the first and second metal layers M1 and M2 will be described in more detail with reference to FIGS. 5C and 6A. The metal interconnection structure MST may include interconnection patterns M1_I and M2_I, etch stop layers EST1 and EST2, conductive vias VI1 and VI2, and interlayer insulating layers 130 and 140.

The first metal layer M1 may include a first etch stop layer EST1, the third interlayer insulating layer 130 on the first etch stop layer EST1, the first conductive via VI1 penetrating the first etch stop layer EST1, and a first interconnection pattern M1_I electrically connected to the first conductive via VI1.

The first etch stop layer EST1 may be provided on the second interlayer insulating layer 120. The first etch stop layer EST1 may be formed of or include, for example, silicon nitride. The first etch stop layer EST1 may be interposed between the second interlayer insulating layer 120 and the third interlayer insulating layer 130.

The third interlayer insulating layer 130 may include a first via insulating layer 1301 and a first pattern insulating layer 1302 on the first via insulating layer 1301. The first via insulating layer 1301 may be disposed on the first etch stop layer EST1. The first via insulating layer 1301 may include an insulating material. The first pattern insulating layer 1302 may include an insulating material.

The first conductive via VI1 may penetrate the first etch stop layer EST1 and the first via insulating layer 1301. The first conductive via VI1 may be in contact with the first etch stop layer EST1 and the first via insulating layer 1301. The first conductive via VI1 may include a conductive material.

The first interconnection pattern M1_I may penetrate the first pattern insulating layer 1302. The first interconnection pattern M1_I may be electrically connected to the first conductive via VI1. The first interconnection pattern M1_I may include a conductive material.

The second metal layer M2 may include a second etch stop layer EST2, the fourth interlayer insulating layer 140 on the second etch stop layer EST2, the second conductive via VI2 penetrating the second etch stop layer EST2, and a second interconnection pattern M2_I electrically connected to the second conductive via VI2.

The second etch stop layer EST2 may be provided on the third interlayer insulating layer 130. The second etch stop layer EST2 may be formed of or include, for example, silicon nitride. The second etch stop layer EST2 may be interposed between the third interlayer insulating layer 130 and the fourth interlayer insulating layer 140.

The fourth interlayer insulating layer 140 may include a second via insulating layer 1401 and a second pattern insulating layer 1402 on the second via insulating layer 1401. The second via insulating layer 1401 may be disposed on the second etch stop layer EST2. The second via insulating layer 1401 may include an insulating material. The second pattern insulating layer 1402 may include an insulating material.

The second conductive via VI2 may penetrate the second etch stop layer EST2 and the second via insulating layer 1401. The second conductive via VI2 may be in contact with the second etch stop layer EST2 and the second via insulating layer 1401. The second conductive via VI2 may include a conductive material.

The second interconnection pattern M2_I may penetrate the second pattern insulating layer 1402. The second interconnection pattern M2_I may be electrically connected to the second conductive via VI2. The second interconnection pattern M2_I may include a conductive material. The second interconnection pattern M1_I may include copper.

A structure (Pa) of the portion ‘P’ of FIG. 5C, according to an embodiment of the inventive concept, will be described in more detail with reference to FIG. 6A. Referring to FIG. 6A, a diffusion prevention pattern ISTa may be interposed between a first interconnection pattern M1a_I and a second conductive via VI2a.

A second interconnection pattern M2_Ia and a selection barrier pattern BSLa enclosing (i.e., extending around) the second conductive via VI2a may be provided. The selection barrier pattern BSLa may be in contact with a bottom surface of the second interconnection pattern M2_Ia, which is not in contact with the second conductive via VI2a. The selection barrier pattern BSLa may cover side surfaces of the second conductive via VI2a. The selection barrier pattern BSLa may include tantalum nitride (TaN). The selection barrier pattern BSLa may be in contact with the second via insulating layer 1401. A portion of the selection barrier pattern BSLa may be interposed between the bottom surface of the second interconnection pattern M2_Ia, which is not in contact with the second conductive via VI2a, and the second via insulating layer 1401.

A bottom surface BSLa_BS of the selection barrier pattern BSLa may be in contact with a top surface ISTa_TS of the diffusion prevention pattern ISTa. A top surface ISTa_TS of the diffusion prevention pattern ISTa may be in contact with the selection barrier pattern BSLa and the second conductive via VI2a. A side surface of the diffusion prevention pattern ISTa may be in contact with the second etch stop layer EST2 and a first interconnection pattern M1_Ia.

A level of a bottom surface ISTa_BS of the diffusion prevention pattern ISTa may be lower than a level of a topmost surface M1_IaTS of the first interconnection pattern M1_Ia in the third direction D3, relative to the upper surface of the substrate 100 (FIG. 5C) as a reference layer. The topmost surface M1_IaTS of the first interconnection pattern M1_Ia may be defined as the first interconnection pattern M1_Ia in contact with the second etch stop layer EST2. A level of the bottom surface ISTa_BS of the diffusion prevention pattern ISTa may be lower than a level of a bottom surface EST2_BS of the second etch stop layer EST2 in the third direction D3, relative to the upper surface of the substrate 100 (FIG. 5C). The bottom surface EST2_BS of the second etch stop layer EST2 may be coplanar with the topmost surface M1_IaTS of the first interconnection pattern M1_Ia in the third direction D3.

A level of the top surface ISTa_TS of the diffusion prevention pattern ISTa may be lower than a level of a top surface EST2_TS of the second etch stop layer EST2 in the third direction D3. The level of the top surface ISTa_TS of the diffusion prevention pattern ISTa may be higher than the level of the topmost surface M1_IaTS of the first interconnection pattern M1_Ia in the third direction D3.

A width M1_IaW of the first interconnection pattern M1_Ia in the first direction D1 may be larger than a width ISTa_BSW of the bottom surface ISTa_BS of the diffusion prevention pattern ISTa in the first direction D1.

The diffusion prevention pattern ISTa may be formed by performing an oxidation process on a portion of a top surface of the first interconnection pattern M1_Ia. The diffusion prevention pattern ISTa may be formed of or include ruthenium oxide. The first interconnection pattern M1_Ia may be formed of or include ruthenium. The second conductive via VI2a may include copper or molybdenum. In an embodiment, a first conductive via VI1a may include ruthenium, and the second interconnection pattern M2_Ia may include copper.

A structure (Pb) of the portion ‘P’ of FIG. 5C, according to an embodiment of the inventive concept, will be described in more detail with reference to FIG. 6B. For concise description, a previously described element may be identified by the same reference number without repeating an overlapping description thereof.

Referring to FIG. 6B, a diffusion prevention pattern ISTb may be interposed between a second interconnection pattern M2_Ib and a second conductive via VI2b.

A selection barrier pattern BSLb may be provided on a bottom surface M2_IbBS of the second interconnection pattern M2_Ib. For example, the selection barrier pattern BSLb may be provided on the bottom surface M2_IbBS of the second interconnection pattern M2_Ib, which is not in contact with the second conductive via VI2b. The selection barrier pattern BSLb may be interposed between the second interconnection pattern M2_Ib and the second via insulating layer 1401.

A bottom surface BSLb_BS of the selection barrier pattern BSLb may be in contact with the second via insulating layer 1401. The bottom surface BSLb_BS of the selection barrier pattern BSLb may be in contact with the top surface 1401_TS of the second via insulating layer 1401. A top surface BSLb_TS of the selection barrier pattern BSLb may be in contact with the second interconnection pattern M2_Ib. The top surface BSLb_TS of the selection barrier pattern BSLb may be in contact with the bottommost surface M2_IbBS of the second interconnection pattern M2_Ib. The bottommost surface M2_IbBS of the second interconnection pattern M2_Ib may be defined as a surface of the second interconnection pattern M2_Ib in contact with the selection barrier pattern BSLb. A top surface ISTb_TS of the diffusion prevention pattern ISTb may be in contact with the second interconnection pattern M2_Ib. A side surface of the diffusion prevention pattern ISTb may be in contact with the selection barrier pattern BSLb, the second via insulating layer 1401, and the second interconnection pattern M2_Ib.

A level of a bottom surface ISTb_BS of the diffusion prevention pattern ISTb may be lower than a level of the bottom surface BSLb_BS of the selection barrier pattern BSLb in the third direction D3, relative to the upper surface of the substrate 100 (see FIG. 5C) as a reference layer. The level of the bottom surface ISTb_BS of the diffusion prevention pattern ISTb may be lower than a level of the top surface 1401_TS of the second via insulating layer 1401 in the third direction D3, relative to the upper surface of the substrate 100 (see FIG. 5C). The level of the bottom surface ISTb_BS of the diffusion prevention pattern ISTb may be lower than a level of the bottommost surface M2_IbBS of the second interconnection pattern M2_Ib in the third direction D3, relative to the upper surface of the substrate 100 (see FIG. 5C).

A level of the top surface ISTb_TS of the diffusion prevention pattern ISTb may be higher than a level of the top surface BSLb_TS of the selection barrier pattern BSLb in the third direction D3, relative to the upper surface of the substrate 100 (see FIG. 5C). The level of the top surface ISTb_TS of the diffusion prevention pattern ISTb may be higher than the level of the bottommost surface M2_IbBS of the second interconnection pattern M2_Ib in the third direction D3, relative to the upper surface of the substrate 100 (see FIG. 5C).

The diffusion prevention pattern ISTb may be formed by performing an oxidation process on a portion of a top surface of the second conductive via VI2b. The diffusion prevention pattern ISTb may include ruthenium oxide. The second interconnection pattern M2_Ib may include copper. The second conductive via VI2b may include ruthenium. In an embodiment, a first interconnection pattern M1_Ia and a first conductive via VI1b may be formed of or include ruthenium.

A structure (Pc) of the portion ‘P’ of FIG. 5C, according to an embodiment of the inventive concept, will be described in more detail with reference to FIG. 6C. For concise description, a previously described element may be identified by the same reference number without repeating an overlapping description thereof.

Referring to FIG. 6C, a diffusion prevention pattern ISTc may be interposed between a first interconnection pattern M1_Ic and a first conductive via VI1c. A selection barrier pattern BSLc may be interposed between the first pattern insulating layer 1302 and the first interconnection pattern M1_Ic and between the first via insulating layer 1301 and the first interconnection pattern M1_Ic. A side surface of the diffusion prevention pattern ISTc may be in contact with the first interconnection pattern M1_Ic, the selection barrier pattern BLSc, and the first via insulating layer 1301. The selection barrier pattern BSLc may be provided on a side surface of the first interconnection pattern M1_Ic and a bottom surface of the first interconnection pattern M1_Ic, which is not in contact with the first conductive via VI1c.

A bottom surface BSLc_BS of the selection barrier pattern BSLc may be in contact with the first via insulating layer 1301. A topmost surface BSLc_TMS of the selection barrier pattern BSLc may be in contact with the second etch stop layer EST2. The topmost surface BSLc_TMS of the selection barrier pattern BSLc may be coplanar with a top surface of the first interconnection pattern M1_Ic in the third direction D3.

A bottommost surface M1_IcBS of the first interconnection pattern M1_Ic may be defined as a surface of the first interconnection pattern M1_Ic in contact with the selection barrier pattern BSLc. A top surface ISTc_TS of the diffusion prevention pattern ISTc may be in contact with the first interconnection pattern M1_Ic. The side surface of the diffusion prevention pattern ISTc may be in contact with the selection barrier pattern BSLc, the first pattern insulating layer 1302, and the first interconnection pattern M1_Ic.

A level of a bottom surface ISTc_BS of the diffusion prevention pattern ISTc may be lower than a level of the bottom surface BSLc_BS of the selection barrier pattern BSLc in the third direction D3, relative to the upper surface of the substrate 100 (see FIG. 5C) as a reference layer. The level of the bottom surface ISTc_BS of the diffusion prevention pattern ISTc may be lower than a level of a top surface 1301_TS of the first via insulating layer 1301 in the third direction D3, relative to the upper surface of the substrate 100 (see FIG. 5C). The level of the bottom surface ISTc_BS of the diffusion prevention pattern ISTc may be lower than a level of a bottommost surface M1_IcBS of the first interconnection pattern M1_Ic in the third direction D3, relative to the upper surface of the substrate 100 (see FIG. 5C).

A level of a top surface ISTc_TS of the diffusion prevention pattern ISTc may be higher than the level of the bottom surface BSLc_BS of the selection barrier pattern BSLc in the third direction D3, relative to the upper surface of the substrate 100 (see FIG. 5C). The level of the top surface ISTc_TS of the diffusion prevention pattern ISTc may be higher than the level of the bottommost surface M1_IcBS of the first interconnection pattern M1_Ic in the third direction D3, relative to the upper surface of the substrate 100 (see FIG. 5C).

A width M1_IcW, in the first direction D1, of the first interconnection pattern M1_Ic may be larger than a width ISTc_TSW, in the first direction D1, of the diffusion prevention pattern ISTc measured at a level of the top surface ISTc_TS of the diffusion prevention pattern ISTc.

The diffusion prevention pattern ISTc may be formed by performing an oxidation process on a portion of a top surface of the first conductive via VI1c. The diffusion prevention pattern ISTc may include ruthenium oxide. The first interconnection pattern M1_Ic may include copper. The first conductive via VI1c may include ruthenium or molybdenum. In an embodiment, a second interconnection pattern M2_Ic and a second conductive via VI2c may be formed of or include copper.

A structure (Pd) of the portion ‘P’ of FIG. 5C, according to an embodiment of the inventive concept, will be described in more detail with reference to FIG. 6D. For concise description, a previously described element may be identified by the same reference number without repeating an overlapping description thereof.

Referring to FIG. 6D, a diffusion prevention pattern ISTd may be interposed between a first interconnection pattern M1d_I and a second conductive via VI2d. In an embodiment, a second interconnection pattern M2_Id and a selection barrier pattern (not shown) enclosing the second conductive via VI2d may be provided, although not shown.

A bottom surface M1_Id_BS of a first interconnection pattern M1_Id may be coplanar with a top surface 1301_TS of the first via insulating layer 1301 in the third direction D3.

A top surface ISTd_TS of the diffusion prevention pattern ISTd may be in contact with the second conductive via VI2d. A side surface of the diffusion prevention pattern ISTd may be in contact with the second etch stop layer EST2 and the first interconnection pattern M1_Id.

A level of a bottom surface ISTd_BS of the diffusion prevention pattern ISTd may be lower than a level of a topmost surface M1_IdTS of the first interconnection pattern M1_Id in the third direction D3, relative to the upper surface of the substrate 100 (see FIG. 5C) as a reference layer. The topmost surface M1_IdTS of the first interconnection pattern M1_Id may be defined as a surface of the first interconnection pattern M1_Id that is in contact with the second etch stop layer EST2. A level of a bottom surface ISTd_BS of the diffusion prevention pattern ISTd may be lower than a level of the bottom surface of the second etch stop layer EST2 in the third direction D3, relative to the upper surface of the substrate 100 (see FIG. 5C). The bottom surface of the second etch stop layer EST2 may be coplanar with the topmost surface M1_IdTS of the first interconnection pattern M1_Id in the third direction D3.

A level of the top surface ISTd_TS of the diffusion prevention pattern ISTd may be lower than the level of the top surface EST2_TS of the second etch stop layer EST2 in the third direction D3, relative to the upper surface of the substrate 100 (see FIG. 5C). The level of the top surface ISTd_TS of the diffusion prevention pattern ISTd may be higher than a level of the topmost surface M1_IdTS of the first interconnection pattern M1_Id in the third direction D3, relative to the upper surface of the substrate 100 (see FIG. 5C).

A width M1_IdW, in the first direction D1, of the first interconnection pattern M1_Id may be larger than a width ISTd_TSW, in the first direction D1, of the top surface ISTd_TS of the diffusion prevention pattern ISTd.

The diffusion prevention pattern ISTd may be formed by depositing ruthenium on a top surface of the first interconnection pattern M1_Ia. The diffusion prevention pattern ISTd may include ruthenium oxide. In an embodiment, the diffusion prevention pattern ISTd may be formed of or include Ru/RuO₂. The first interconnection pattern M1_Id and a first conductive via VI1d may include copper. The second conductive via VI2d and the second interconnection pattern M2_Id may be formed of or include ruthenium.

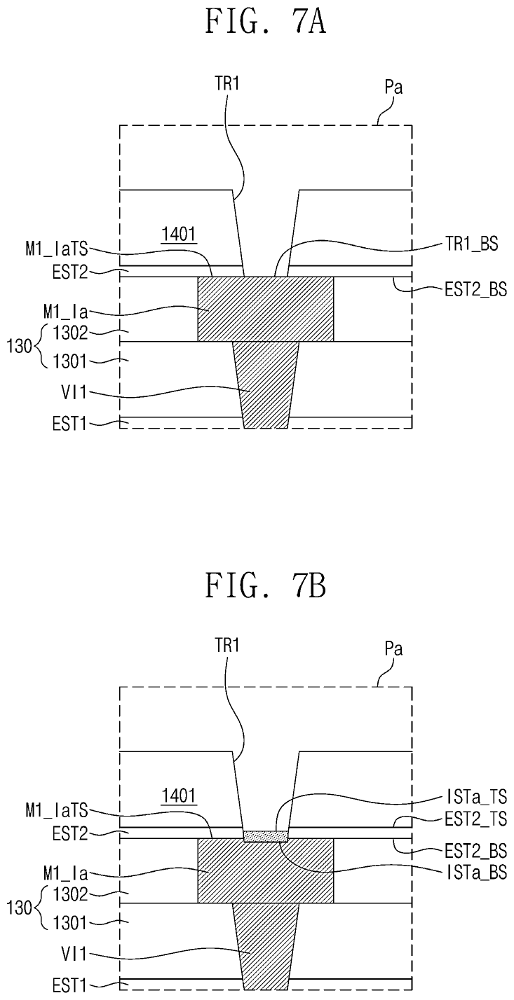

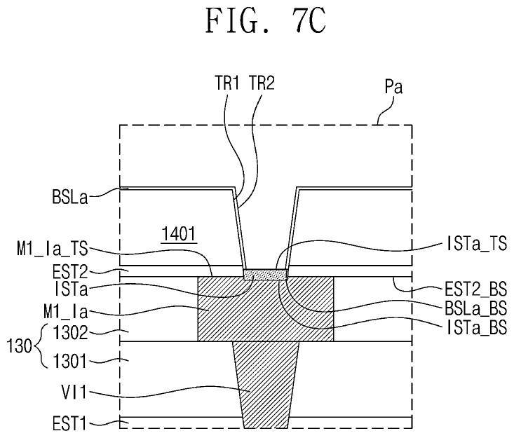

FIGS. 7A to 7C are cross-sectional views illustrating intermediate processes in an example method of fabricating the semiconductor device of FIG. 6A, according to one or more embodiments. In detail, FIGS. 7A to 7C are cross-sectional views illustrating a method of fabricating a metal interconnection structure of a semiconductor device, according to an embodiment of the inventive concept.

Referring to FIGS. 5C, 6A, and 7A, the first etch stop layer EST1 may be formed on the second interlayer insulating layer 120, after the formation of the active and gate contacts AC and GC, respectively. The first via insulating layer 1301 on the first etch stop layer EST1, the first pattern insulating layer 1302 on the first via insulating layer 1301, the first conductive via VI1 penetrating (i.e., extending through) the first via insulating layer 1301, the first interconnection pattern M1_Ia on the first conductive via VI1, the second etch stop layer EST2 on the first interconnection pattern M1_Ia, the second via insulating layer 1401 on the second etch stop layer EST2, and a first trench TR1 extending into the second etch stop layer EST2 and the second via insulating layer 1401 in the third direction D3 may be provided. The first interconnection pattern M1_Ia may include ruthenium (Ru). The first conductive via VI1 and the first interconnection pattern M1_Ia may be formed through a semi-damascene process and a ruthenium etching process.

A bottom surface EST2_BS of the second etch stop layer EST2 may be coplanar with a topmost surface M1_IaTS of the first interconnection pattern M1_Ia in the third direction D3, relative to the upper surface of the substrate 100 (see FIG. 5C). A portion of the topmost surface M1_IaTS of the first interconnection pattern M1_Ia may be exposed through the first trench TR1. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. A side surface of the first trench TR1 may be inclined at an angle. A portion of the topmost surface M1_laTS of the first interconnection pattern M1_Ia may be exposed through a bottom surface TR1_BS of the first trench TR1.

Referring to FIGS. 7B and 7C, an oxidation process or a RuO₂ deposition process may be selectively performed on the topmost surface M1_IaTS of the first interconnection pattern M1_Ia, which is exposed through the bottom surface TR1_BS of the first trench TR1 (FIG. 7A). As a result, the diffusion prevention pattern ISTa may be locally formed in the first trench TR1. The diffusion prevention pattern ISTa may be formed of or include ruthenium oxide. The diffusion prevention pattern ISTa may be formed of or include RuO₂.

During the formation of the diffusion prevention pattern ISTa, a portion of the first interconnection pattern M1_Ia adjacent to the exposed topmost surface M1_IaTS may be oxidized. In this case, the bottommost surface ISTa_BS of the diffusion prevention pattern ISTa may be located at a level that is lower than the topmost surface M1_IaTS of the first interconnection pattern M1_Ia in the third direction D3, relative to the upper surface of the substrate 100 (see FIG. 5C). The level of the bottommost surface ISTa_BS of the diffusion prevention pattern ISTa may be lower than a level of the bottom surface EST2_BS of the second etch stop layer EST2 in the third direction D3, relative to the upper surface of the substrate 100 (see FIG. 5C). The diffusion prevention pattern ISTa may be formed such that a level of the top surface ISTa_TS of the diffusion prevention pattern ISTa is lower than a level of the top surface EST2_TS of the second etch stop layer EST2 in the third direction D3, relative to the upper surface of the substrate 100 (see FIG. 5C).

Referring to FIG. 7C, the selection barrier pattern BSLa may be formed to conformally cover side and top surfaces of the first trench TR1. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The top surface ISTa_TS of the diffusion prevention pattern ISTa may be in contact with the bottom surface BSLa_BS of the selection barrier pattern BSLa. As a result of the formation of the diffusion prevention pattern ISTa, a second trench TR2 may be formed.

Referring back to FIG. 6A, the second conductive via VI2a may be formed to fill the second trench TR2. The second interconnection pattern M2_Ia may be formed on the second conductive via VI2a. In an embodiment, the second conductive via VI2a and the second interconnection pattern M2_Ia may be formed by forming a copper seed layer and performing a plating process.

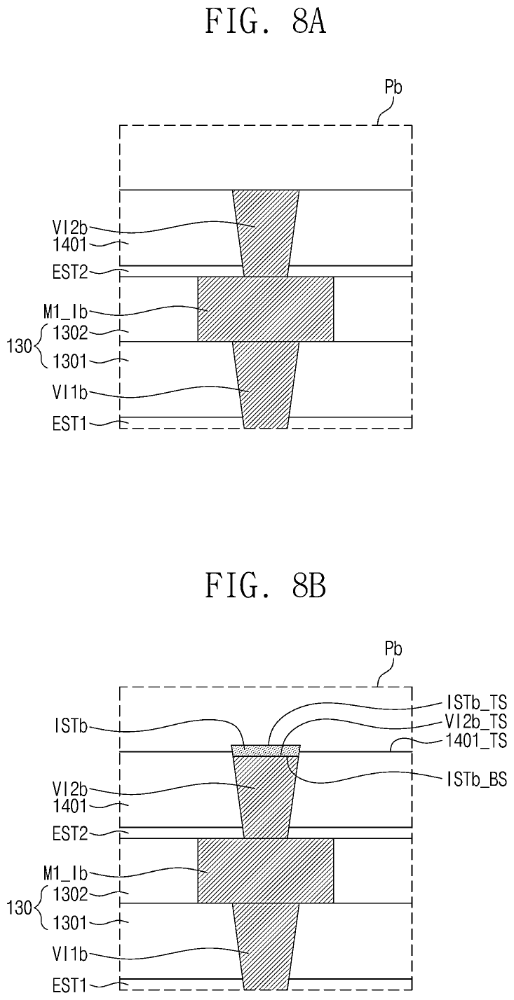

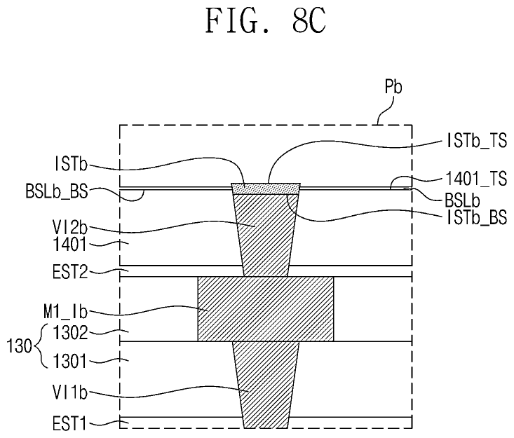

FIGS. 8A to 8C are cross-sectional views illustrating intermediate processes in an example method of fabricating the semiconductor device of FIG. 6B, according to one or more embodiments. In detail, FIGS. 8A to 8C are cross-sectional views illustrating a method of fabricating a metal interconnection structure of a semiconductor device, according to an embodiment of the inventive concept. For concise description, a previously described element may be identified by the same reference number without repeating an overlapping description thereof.

Referring to FIG. 8A, the third interlayer insulating layer 130 including the first via insulating layer 1301 and the first pattern insulating layer 1302 may be formed on the first etch stop layer EST1. Thereafter, a first via VI1b may be formed to penetrate (i.e., extend through) the first via insulating layer 1301 in the third direction D3. The first interconnection pattern M1_Ib may be formed to penetrate the first pattern insulating layer 1302 in the third direction D3. The second etch stop layer EST2 may be formed on the first interconnection pattern M1_Ib and the first pattern insulating layer 1302. The second via insulating layer 1401 may be formed on the second etch stop layer EST2. A trench (not shown) may be formed to penetrate the second via insulating layer 1401, and then, a second via VI2b may be formed in the trench. A top surface of the second via VI2b may be exposed to the outside of the second via insulating layer 1401. The second via VI2b and the first interconnection pattern M1_Ib may be formed of or include ruthenium (Ru).

Referring to FIG. 8B, the diffusion prevention pattern ISTb may be formed on the exposed second via VI2b. For example, an upper portion of the exposed second via VI2b may be selectively oxidized, or a RuO2 layer may be deposited on the second via VI2b. As a result, the diffusion prevention pattern ISTb may be formed on the second via VI2b. The diffusion prevention pattern ISTb may include ruthenium oxide. In an embodiment, the diffusion prevention pattern ISTb may be formed of or include RuO₂.

An upper portion of the second via VI2b, which is exposed in the process of forming the diffusion prevention pattern ISTb, may be selectively oxidized. In this case, a top surface VI2b_TS of the second via VI2b may be in contact with the bottom surface ISTb_BS of the diffusion prevention pattern ISTb. The level of the top surface 1401_TS of the second via insulating layer 1401 may be higher than a level of the top surface VI2b_TS of the second via VI2b in the third direction D3, relative to the upper surface of the substrate 100 (see FIG. 5C) as a reference layer. The level of the top surface 1401_TS of the second via insulating layer 1401 may be higher than the level of the bottom surface ISTb_BS of the diffusion prevention pattern ISTb in the third direction D3, relative to the upper surface of the substrate 100 (see FIG. 5C). The level of the top surface 1401_TS of the second via insulating layer 1401 may be lower than the level of the top surface ISTb_TS of the diffusion prevention pattern ISTb in the third direction D3, relative to the upper surface of the substrate 100 (see FIG. 5C).

Referring to FIG. 8C, a selection barrier pattern BLSb may be conformally formed on the second via insulating layer 1401. The bottom surface BSLb_BS of the selection barrier pattern BLSb may be in contact with the top surface 1401_TS of the second via insulating layer 1401. A level of the bottom surface BSLb_BS of the selection barrier pattern BLSb may be higher than the level of the bottom surface ISTb_BS of the diffusion prevention pattern ISTb in the third direction D3, relative to the upper surface of the substrate 100 (see FIG. 5C). The selection barrier pattern BLSb may be deposited such that a level of the top surface BSLb_TS is lower than the level of the top surface ISTb_TS of the diffusion prevention pattern ISTb in the third direction D3, relative to the upper surface of the substrate 100 (see FIG. 5C).

Referring back to FIG. 6B, the second interconnection pattern M2_Ib may be formed to cover the diffusion prevention pattern ISTb and the selection barrier pattern BSLb. In an embodiment, the second interconnection pattern M2_Ib may be formed by depositing copper.

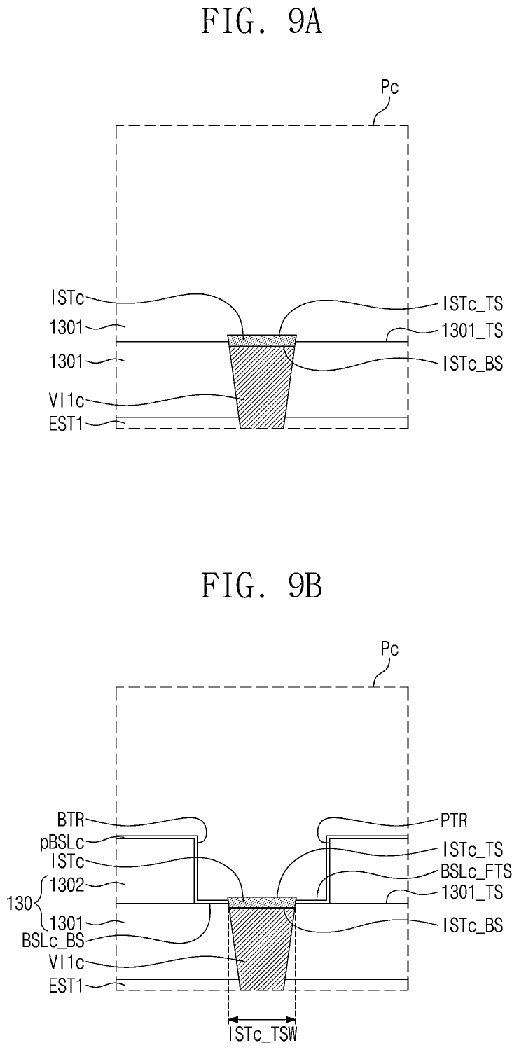

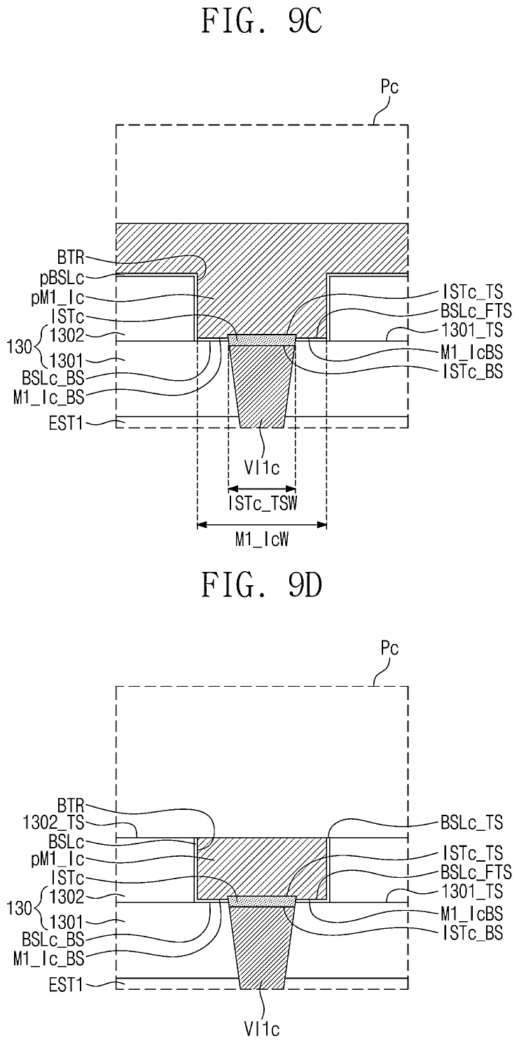

FIGS. 9A to 9D are cross-sectional views illustrating intermediate processes in an example method of fabricating the semiconductor device of FIG. 6C, according to one or more embodiments. In detail, FIGS. 9A to 9D are cross-sectional views illustrating a method of fabricating a metal interconnection structure of a semiconductor device, according to an embodiment of the inventive concept. For concise description, a previously described element may be identified by the same reference number without repeating an overlapping description thereof.

Referring to FIG. 9A, the first via insulating layer 1301 may be formed on the first etch stop layer EST1. A trench (not shown) may be formed on the first etch stop layer EST1 to penetrate the first via insulating layer 1301. The first via VI1c may be formed to fill the trench (not shown). The first via VI1c may be formed of or include a metallic material. The first via VI1c may be formed of or include at least one of, for example, W, Ru, Mo, or Co. The diffusion prevention pattern ISTc may be formed on the first via VI1c. The diffusion prevention pattern ISTc may be formed of or include, for example, Ru/RuO₂. The level of the top surface ISTc_TS of the diffusion prevention pattern ISTc may be higher than a level of the top surface 1301_TS of the first via insulating layer 1301 in the third direction D3, relative to the upper surface of the substrate 100 (see FIG. 5C). The level of the bottom surface ISTc_BS of the diffusion prevention pattern ISTc may be lower than the level of the top surface 1301_TS of the first via insulating layer 1301 in the third direction D3, relative to the upper surface of the substrate 100 (see FIG. 5C).

Referring to FIG. 9B, the first pattern insulating layer 1302 may be formed on the first via insulating layer 1301. In an embodiment, an etch stop layer (not shown) may be formed on the first via insulating layer 1301, and then, the first pattern insulating layer 1302 may be formed thereon. Thereafter, a pattern trench PTR may be formed by patterning the first pattern insulating layer 1302. In an embodiment, the formation of the pattern trench PTR may include selectively etching the first pattern insulating layer 1302, and not etching the diffusion prevention pattern ISTc. As a result, a portion of the top surface 1301_TS of the first pattern insulating layer 1302 and the top surface ISTc_TS of the diffusion prevention pattern ISTc may be exposed to the outside.

A preliminary selection barrier pattern pBLSc may be formed to conformally cover the top surface 1302_TS of the first pattern insulating layer 1302 and the side surface of the first pattern insulating layer 1302, which are exposed to the outside. The preliminary selection barrier pattern pBLSc may be in contact with the side surface of the diffusion prevention pattern ISTc. The preliminary selection barrier pattern pBLSc may be deposited to expose the top surface ISTc_TS of the diffusion prevention pattern ISTc. As a result of the formation of the preliminary selection barrier pattern pBLSc, a barrier trench BTR may be defined. The diffusion prevention pattern ISTc may have the width ISTc_TSW, in the first direction D1, at a level of the exposed top surface ISTc_TS of the diffusion prevention pattern ISTc.

Referring to FIG. 9C, a preliminary first interconnection pattern pM1_Ic may be formed on the preliminary selection barrier pattern pBLSc. The preliminary first interconnection pattern pM1_Ic may be formed to fill the barrier trench BTR and cover the preliminary selection barrier pattern pBLSc. The barrier trench BTR filled with preliminary first interconnection pattern pM1_Ic may define the width M1_IcW, in the first direction D1, of the preliminary first interconnection pattern pM1_Ic, which will be formed in a subsequent step. The preliminary first interconnection pattern pM1_Ic may include copper. The width M1_IcW, in the first direction D1, of the preliminary first interconnection pattern pM1_Ic may be larger than the width ISTc_TSW, in the first direction D1, of the diffusion prevention pattern ISTc measured at a level of the top surface ISTc_TS.

Referring to FIG. 9D, the preliminary selection barrier pattern pBLSc and the preliminary first interconnection pattern pM1_Ic may be etched to a level of a top surface 1302_TS of the first pattern insulating layer 1302. The preliminary first interconnection pattern pM1_Ic may be etched to fill the barrier trench BTR. The preliminary first interconnection pattern pM1_Ic and the selection barrier pattern BLSc may be formed. In this case, the top surface 1302_TS of the first pattern insulating layer 1302, a top surface BLSc_TS of the selection barrier pattern BLSc, and a top surface of the preliminary first interconnection pattern pM1_Ic may be exposed.

Referring back to FIG. 6C, the second etch stop layer EST2, the second via insulating layer 1401, the second via VI2c, and the second interconnection pattern M2_Ic may be formed on the exposed top surface 1302_TS of the first pattern insulating layer 1302, the exposed top surface BLSc_TS of the selection barrier pattern BLSc, and the exposed top surface of the preliminary first interconnection pattern pM1_Ic.

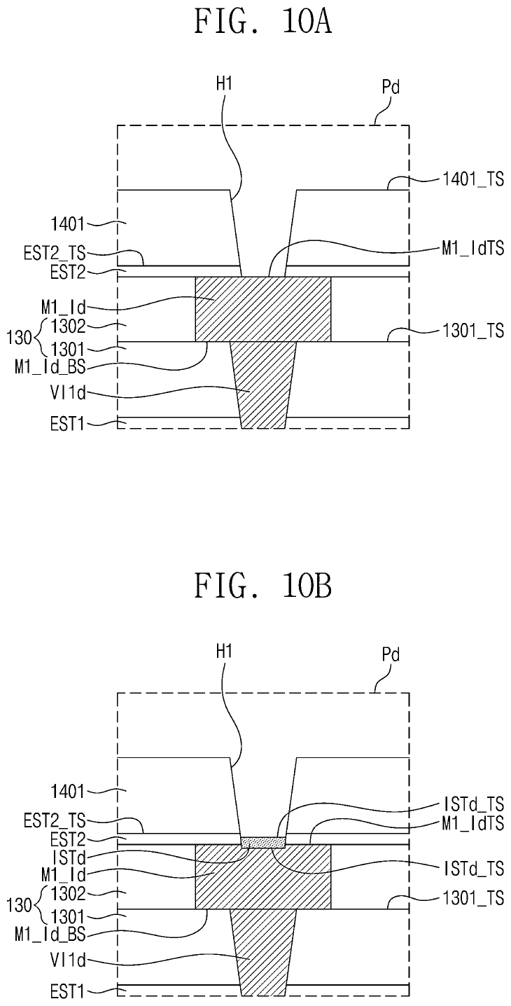

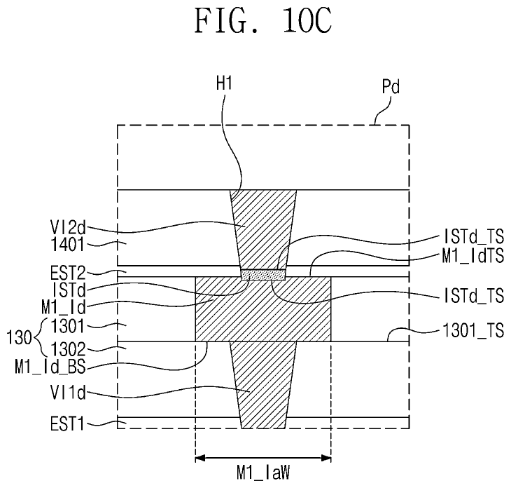

FIGS. 10A to 10C are cross-sectional views illustrating intermediate processes in an example method of fabricating the semiconductor device of FIG. 6D, according to one or more embodiments. In detail, FIGS. 10A to 10C are cross-sectional views illustrating a method of fabricating a metal interconnection structure of a semiconductor device, according to an embodiment of the inventive concept. For concise description, a previously described element may be identified by the same reference number without repeating an overlapping description thereof.

Referring to FIG. 10A, the first etch stop layer EST1 may be formed on the second interlayer insulating layer 120. The first via insulating layer 1301 on the first etch stop layer EST1, the first pattern insulating layer 1302 on the first via insulating layer 1301, the first via VI1d penetrating the first via insulating layer 1301, the first interconnection pattern M1_Id on the first via VI1d, the second etch stop layer EST2 on the first interconnection pattern M1_Id, the second via insulating layer 1401 on the second etch stop layer EST2, and a first hole (i.e., opening) H1 penetrating (i.e., extending into or through) the second etch stop layer EST2, in the third direction D3, and the second via insulating layer 1401 may be provided. The first interconnection pattern M1_Id may be formed of or include copper. The formation of the first via VI1 and the first interconnection pattern M1_Ia may be formed through a damascene process and a plating process. The first interconnection pattern M1_Id may be formed to have a bottom surface M1_IdBS that is coplanar with the top surface 1301_TS of the first via insulating layer 1301 in the third direction D3.

A portion of the topmost surface M1_IdTS of the first interconnection pattern M1_Id may be exposed through the first hole H1. A side surface of the first hole H1 may be inclined at an angle.

Referring to FIG. 10B, a ruthenium layer may be selectively deposited on the topmost surface M1_IdTS of the first interconnection pattern M1_Id. In this case, the diffusion prevention pattern ISTd may be formed in the first hole H1. The diffusion prevention pattern ISTd may be formed to have a top surface that is lower than the top surface EST2_TS of the second etch stop layer EST2 in the third direction D3, relative to the upper surface of the substrate 100 (FIG. 5C) as a reference layer. The diffusion prevention pattern ISTd may be formed of or include ruthenium oxide. In an embodiment, the diffusion prevention pattern ISTd may be formed of or include Ru/RuO₂.

In the process of forming the diffusion prevention pattern ISTd, a portion of the first interconnection pattern M1_Id adjacent to the exposed topmost surface M1_IdTS may be oxidized and then may be removed. In this case, a level of the bottommost surface ISTd_BS of the diffusion prevention pattern ISTd may be lower than a level of the topmost surface M1_IdTS of the first interconnection pattern M1_Id in the third direction D3, relative to the upper surface of the substrate 100 (FIG. 5C). A level of the top surface ISTa_TS of the diffusion prevention pattern ISTa may be lower than the level of the top surface EST2_TS of the second etch stop layer EST2 in the third direction D3, relative to the upper surface of the substrate 100 (FIG. 5C).

Referring to FIG. 10C, the second conductive via VI2d may be formed to fill the first hole H1. The top surface ISTd_TS of the diffusion prevention pattern ISTd may be covered with the second conductive via VI2d. The second conductive via VI2d may be formed of or include ruthenium (Ru).

Referring back to FIG. 6D, the second interconnection pattern M2_Id may be formed on the second conductive via VI2d. The second interconnection pattern M2_Id may be formed by performing a ruthenium etching process.

According to an embodiment of the inventive concept, a three-dimensional field effect transistor may include a diffusion prevention pattern, which is interposed between a metal pattern and a conductive via and contains ruthenium oxide. Thus, it may be possible to prevent diffusion between the metal pattern and the conductive via. In addition, since the diffusion prevention pattern has low resistance, it may be possible to improve the electrical and reliability characteristics of the semiconductor device.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including an active pattern;
a channel pattern on the active pattern, the channel pattern comprising a plurality of semiconductor patterns which are stacked in a vertical direction perpendicular to an upper surface of the substrate, the plurality of semiconductor patterns spaced apart from each other in the vertical direction;
a gate electrode on the plurality of semiconductor patterns;
a gate contact electrically connected to the gate electrode;
a first metal layer on the gate contact, the first metal layer comprising a first conductive via and a first interconnection pattern on the first conductive via;
a second metal layer on the first metal layer, the second metal layer comprising a second conductive via and a second interconnection pattern on the second conductive via; and
a diffusion prevention pattern between the first interconnection pattern and the second conductive via,
wherein a level of a bottom surface of the diffusion prevention pattern is lower than a level of the topmost surface of the first interconnection pattern in the vertical direction, relative to the upper surface of the substrate.

2. The semiconductor device of claim 1, wherein the diffusion prevention pattern comprises RuO₂ or Ru/RuO₂.

3. The semiconductor device of claim 1, wherein the first interconnection pattern comprises ruthenium, and
the second conductive via comprises copper or molybdenum.

4. The semiconductor device of claim 1, wherein the first interconnection pattern comprises copper, and
the second conductive via comprises ruthenium.

5. The semiconductor device of claim 1, wherein a width of the first interconnection pattern, in a horizontal direction parallel to the upper surface of the substrate, is larger than a width, in the horizontal direction, of the bottom surface of the diffusion prevention pattern.

6. The semiconductor device of claim 1, wherein the first metal layer comprises a first etch stop layer in contact with the first conductive via,
the second metal layer comprises a second etch stop layer on the first interconnection pattern, and
a level of a top surface of the diffusion prevention pattern is lower than a level of a top surface of the first etch stop layer in the vertical direction, relative to the upper surface of the substrate.

7. The semiconductor device of claim 6, further comprising a selection barrier pattern extending around the second interconnection pattern and the second conductive via,
wherein the selection barrier pattern is on side surfaces of the second conductive via.

8. The semiconductor device of claim 7, wherein a bottom surface of the selection barrier pattern is in contact with a top surface of the diffusion prevention pattern.

9. The semiconductor device of claim 7, wherein a top surface of the diffusion prevention pattern is in contact with the selection barrier pattern and the second conductive via, and
a side surface of the diffusion prevention pattern is in contact with the second etch stop layer and the first interconnection pattern.

10. A semiconductor device, comprising:
a substrate including an active pattern;
a channel pattern on the active pattern, the channel pattern comprising a plurality of semiconductor patterns which are stacked in a vertical direction perpendicular to an upper surface of the substrate and spaced apart from each other in the vertical direction;
a source/drain pattern connected to the channel pattern;
a gate electrode on the plurality of semiconductor patterns;
an active contact electrically connected to the source/drain pattern;
a metal interconnection structure on the active contact, the metal interconnection structure comprising a conductive via and an interconnection pattern on the conductive via; and
a diffusion prevention pattern between the interconnection pattern and the conductive via,
wherein a level of a top surface of the diffusion prevention pattern is different from a level of a bottommost surface of the interconnection pattern in contact with the diffusion prevention pattern in the vertical direction, relative to the upper surface of the substrate, and
the diffusion prevention pattern comprises ruthenium oxide.

11. The semiconductor device of claim 10, further comprising:
a via insulating layer extending around the conductive via; and
a selection barrier pattern between the via insulating layer and the interconnection pattern,
wherein the level of the top surface of the diffusion prevention pattern is lower than a level of a top surface of the selection barrier pattern in the vertical direction, relative to the upper surface of the substrate.

12. The semiconductor device of claim 11, wherein the selection barrier pattern comprises tantalum nitride, and
the interconnection pattern and the conductive via comprise different materials from each other.

13. The semiconductor device of claim 10, wherein the metal interconnection structure comprises a first metal layer and a second metal layer on the first metal layer,
the conductive via comprises a first conductive via in the first metal layer and a second conductive via in the second metal layer,
the interconnection pattern comprises a first interconnection pattern in the first metal layer and a second interconnection pattern in the second metal layer, and
the diffusion prevention pattern is between the second conductive via and the second interconnection pattern.

14. The semiconductor device of claim 13, further comprising a selection barrier pattern in contact with a side surface of the diffusion prevention pattern,
wherein a level of a top surface of the selection barrier pattern is lower than the level of the top surface of the diffusion prevention pattern in the vertical direction, relative to the upper surface of the substrate.

15. The semiconductor device of claim 10, wherein the metal interconnection structure comprises a first metal layer and a second interconnection layer on the first metal layer,
the conductive via comprises a first conductive via in the first metal layer and a second conductive via in the second metal layer,
the interconnection pattern comprises a first interconnection pattern in the first metal layer and a second interconnection pattern in the second metal layer, and
the diffusion prevention pattern is between the first conductive via and the first interconnection pattern.

16. The semiconductor device of claim 15, further comprising:
a first pattern insulating layer extending around the first interconnection pattern;
a first via insulating layer extending around the first conductive via; and
a selection barrier pattern between the first pattern insulating layer and the first interconnection pattern and between the first via insulating layer and the first interconnection pattern,
wherein a side surface of the diffusion prevention pattern is in contact with the first interconnection pattern, the selection barrier pattern, and the first via insulating layer.

17. The semiconductor device of claim 15, further comprising:
a selection barrier pattern extending around a portion of a bottom surface of the first interconnection pattern and a side surface of the first interconnection pattern; and
an etch stop layer on the first interconnection pattern,
wherein the topmost surface of the selection barrier pattern is coplanar with the etch stop layer in the vertical direction.

18. A semiconductor device, comprising:
a substrate including an active pattern;
a device isolation layer defining the active pattern;
a channel pattern on the active pattern, the channel pattern comprising a plurality of semiconductor patterns which are stacked in a vertical direction perpendicular to an upper surface of the substrate and spaced apart from each other in the vertical direction;
a gate electrode on the plurality of semiconductor patterns;
a gate insulating layer between the gate electrode and adjacent ones of the semiconductor patterns;
a gate contact electrically connected to the gate electrode;
a first metal layer on the substrate, the first metal layer comprising a first conductive via, a first interconnection pattern on the first conductive via, and a first via insulating layer extending around the first conductive via;
a second metal layer on the first metal layer, the second metal layer comprising a second conductive via and a second interconnection pattern on the second conductive via;
a diffusion prevention pattern between the first conductive via and the first interconnection pattern; and
a selection barrier pattern extending around a portion of a bottom surface of the first interconnection pattern and a side surface of the first interconnection pattern,
wherein a side surface of the diffusion prevention pattern is in contact with the first interconnection pattern, the selection barrier pattern, and the first via insulating layer.

19. The semiconductor device of claim 18, wherein the selection barrier pattern comprises tantalum nitride.

20. The semiconductor device of claim 18, wherein the diffusion prevention pattern comprises ruthenium oxide,
the first conductive via comprises ruthenium, and
the first interconnection pattern comprises copper.
